(19) United States
(12) Patent Application Publication
(10) Pub. No.: US 2008/0026598 A1
(43) Pub. Date: Jan. 31, 2008

(54) Semiconductor manufacturing device and method

(76) Inventors: Taek Yong Jang, Suwon-City (KR); Byoung Il Lee, Seongnam-City (KR); Young Ho Lee, Yongin-City (KR); Kwan Sun Hur, Hwasung-city (KR); Sueng Beom Baek, Dongduchon-City (KR)

Correspondence Address: Ditthavong Mori & Steiner, P.C., 918 Prince Street, Alexandria, VA, 22314, US

(21) Appl. No.: 11/493,359

(22) Filed: Jul. 26, 2006

(51) Int. Cl. H01L 21/00

(52) U.S. Cl. 438/795; 422/187

(57) ABSTRACT

A semiconductor manufacturing device and a method thereof capable of processing semiconductor substrates having a large diameter in a state that the semiconductor substrates keep standing and are opposed to each other are disclosed. The semiconductor manufacturing device includes a reaction chamber for providing an airtight process space; a boat including a pair of susceptors as the processing device mounted to the reaction chamber; a driving device for rotating the susceptors; a heater; a loading device for inserting the heater into an inner space of the susceptors; a supply nozzle and an exhaust nozzle; and a lifting device for inserting the exhaust nozzle into the space between the holders. The semiconductor manufacturing device according to present invention can prevent the transformation of the semiconductor substrate and the contamination owing to the minute dust and maintain the uniform temperature gradient of the semiconductor substrate.

### BACKGROUND OF THE INVENTION

1. Field of the Invention

The present invention relates to a semiconductor manufacturing device and a method thereof, and more particularly to a semiconductor manufacturing device and a method thereof capable of processing semiconductor substrates having a large diameter in a state that the semiconductor substrates keep standing and are opposed to each other.

2. Description of the Prior Art

Generally, in an epitaxial semiconductor manufacturing process, a single crystal is grown on a wafer surface in order to maximally decrease the defect of the wafer surface. Since the epitaxial semiconductor process can control the minute defect such as a COP and so on existed in the wafer surface or around the wafer surface and improve a GOI (Gate Oxide Integrity) characteristic after the manufacturing of the device, it has been actively developed.

In the epitaxial layer, a silicon source gas such as Sicl₄, SiHCl₃, SiH₂Cl₂ or HiH₄ and so forth are supplied to the silicon wafer of a high temperature by means of a hydrogen carrier and the single silicon is grown on the substrate through a H—Si—Cl based reaction by means of a chemical vapor deposition.

In this epitaxial growth method, the wafer is treated with a single wafer type, in consideration of a high temperature environment leading to the deflection of the wafer, a distribution of the reaction gas and the evenness of the film.

In this device, the minute structure and the growth result of the evaporation film is determined by a nucleation process and a surface diffusion on the growth interfacing layer. The substrate temperature, the pressure of a reaction chamber and the gas formation have an effect on it.

Especially, the characteristic of a chemical reactant and a gas dynamics and a hydrokinetics for providing a geometry are important factor in the chemical vapor deposition. For this reason, the reaction gas is injected and discharged from the upper portion to lower portion of the reaction chamber and the semiconductor substrate is arranged in a flow pattern.

However, in the evaporation device of the single wafer type, there is a fundamental problem in that the processing volume is limited.

That is, in the single wafer type, a loading step, an evaporation step and an unloading step are performed at a pure status in order, so that the processing volume is basically limited. Accordingly, in order to produce in large quantities, it is necessary to arrange a large evaporation device of the single wafer type by a unit. However, it is not desirable that the productivity thereof is lowered in terms of the insurance of the physical space and the input of the device.

In the meantime, the semiconductor manufacturing process requires a strict cleanness. However, where the semiconductor is putted into the reaction chamber to process it, a minute particles drops from a nozzle or boat at the semiconductor substrate, thereby contaminating the substrate surface.

In order to overcome the problem, a semiconductor manufacturing device of a pair of wafers type is positively developed. For example, the semiconductor manufacturing device of a pair of wafers type is disclosed in Japanese patent publication Nos. 2000-124135, 2000-124134 and 2000-49080 and so on.

That is, in the semiconductor manufacturing device of a pair of wafers type, the semiconductor substrates 100 keep standing and are opposed to each other and then, the nozzle is arranged at the space between the opposed substrate surfaces (process treating surfaces). Thereafter, the reaction gas is injected into the space to progress the process (note Japanese patent publication No. 2000-124135).

In this case, there are merits in that the productivity is increased owing to the process of a pair of substrates, the contamination of the substrate is prevented, and a lamination flow of the reaction gas can be formed on the opposed substrate surfaces.

In order to process the opposed semiconductor substrates, susceptors for standing the semiconductor substrate is mounted to the boat and holders, on which the semiconductor substrates are placed, are mounted on the susceptors.

Also, the susceptor is supported through the supporting roller and a driving pin for rotating through a driving gas is formed at the outer circumference of the susceptors (note Japanese patent publication Nos. 2000-124134 and 490985).

However, there are many problems owing to the facing condition of a pair of semiconductor substrate.

Firstly, in the susceptor, it is necessary to prevent the contamination and the transformation of the semiconductor substrate and so on.

More concretely, the susceptor is paralleled with the gravity direction in order to keep the semiconductor substrate 100 standing and to be opposed to each other. Also, the holder, on which the semiconductor substrate is loaded, is loaded on the susceptor again.

Each holder has an elastic attaching means elastically attached to the outer circumference of the semiconductor substrate in order to load the standing semiconductor substrate thereon. Also, since the semiconductor substrate is rotated during the process, it requires an elastic power fit for it (note Japanese patent publication No. 2000-49098).

However, in a high temperature environment more than 1000° C. for treating the epitaxial process, the partial load through the elastic attaching means leads to the transformation of the semiconductor substrate. Accordingly, it is necessary to exclude the partially elastic attachment.

In the meantime, in order to rotate the semiconductor substrate during the process, the outer circumference of the susceptor is supported through the supporting roller and the susceptor is rotated by means of the driving pin and the driving gas provided by the susceptor (note Japanese patent publication No. 2000-124134).

For this reason, the friction between the supporting roller and the outer circumference of the susceptor is essentially generated. There is a problem in that the minute particle is penetrated into the process space between the opposed semiconductor substrates, thereby contaminating the substrate surface.

Also, the supply of the driving gas for rotating the susceptor inside the reaction chamber acts as an external disturbance in the process of a low-pressure environment.

Moreover, it is necessary to control the revolution number of the semiconductor substrate during the epitaxial process. However, in the conventional device, since the driving device is not directly connected to the susceptor, it is difficulty to control the revolution number. On the contrary, where the driving device is directly connected to the susceptor, there is a problem in that the driving device (motor) putted into the reaction chamber is damaged in a high temperature environment, thereby it cannot rotate the susceptor.

Furthermore, there is a problem in that it is difficulty to sufficiently ensure the evenness against the temperature gradient.

More concretely, as described above, the temperature and the reaction gas are important factor in the epitaxial process. Also, the semiconductor substrates are opposed to each other in the flow pattern of the reaction gas flowing from the upper portion to lower portion of the reaction chamber.

Under this condition, the initial section of the reaction gas injection has an effect on the temperature gradient. That is, during the initial injection of the reaction gas, the reaction gas of the room temperature allows the upper portion of the semiconductor substrate to produce a cooling area.

Also, in the heater itself, the peripheral portion of the semiconductor substrate is lower than the center of the semiconductor substrate in terms of the temperature. That is, since the heating source of the heater is interfered with the room temperature outside the boundary thereof, the drop of the temperature is generated at the outside of the boundary, thereby having an effect on the uniform temperature gradient of the semiconductor substrate.

It cannot settle the difference of the temperature between the central portion and the peripheral portion by the rotation of the semiconductor substrate. That is, where the difference of the temperature is generated in the same circumference region, it can settle the difference of the temperature by the rotation of the semiconductor substrate. However, where the difference of the temperature is generated between different circumference regions, it cannot settle the difference of the temperature by the rotation of the semiconductor substrate.

Accordingly, in the process of a pair of semiconductor substrate, it is necessary to solve the deviation of the temperature gradient.

Also, there is a structural problem in that the interference between the heater and the susceptor can be generated during loading the susceptor on the reaction chamber.

In a state that the holder having a pair of the semiconductor substrates is loaded on the susceptor, in order to face the semiconductor substrates inside a narrow gap while being rotated by the supporting roller, the susceptor assumes the convex form in the direction of the opposed surface and the concave form (groove) in the direction of the inside thereof.

Here, in the conventional semiconductor manufacturing device, the heater is mounted to and separated from the outer circumference of the susceptor when putting the susceptor in the reaction chamber.

However, since the heating surface of the heater is separated from the space between the semiconductor substrates, it is difficulty to sufficiently heat the substrate surface. Accordingly, there is a troublesome problem in that it is necessary to insert the heater into the concave portion of the susceptor after the loading of the susceptor, so as to approach the semiconductor substrate to the heating source of the heater.

Moreover, in the conventional semiconductor manufacturing device, there is another problem in that it is difficulty to properly arrange the exhaust nozzle.

More concretely, the temperature and the reaction gas are important factor in the epitaxial process. Also, the semiconductor substrates are opposed to each other in the flow pattern of the reaction gas flowing from the upper portion to lower portion of the reaction chamber.

Here, since the exhaust nozzle is maximally closed to the space between the opposed holders in order to reomove the injected reaction gas, the exhaust nozzle requires the suction portion of a large area.

That is, the exhaust nozzle is maximally close between the opposed holders in order to collect the reaction gas. Here, in the Japanese patent publication No. 2000-124135 and so on, the exhaust nozzle loaded with the boat is maximal close to the space between the semiconductor substrates.

However, when the semiconductor substrate of a large diameter is loaded on the reaction chamber, since the moving range of the boat is large, it is not desirable in terms of a reliance that the boat is provided together with the exhaust nozzle and its peripheral device.

### SUMMARY OF THE INVENTION

Accordingly, the present invention has been made to solve the above-mentioned problems occurring in the prior art, and an object of the present invention is to provide a semiconductor manufacturing device and a method thereof capable of processing semiconductor substrates having a large diameter in a state that the semiconductor substrates keep standing and are opposed to each other.

Anther object of the present invention is to provide a semiconductor manufacturing device and a method thereof capable of preventing transformation of a semiconductor substrate through an elastic attaching means of the holder and sufficiently supporting the substrate under an environment of a high temperature.

Further anther object of the present invention is to provide a semiconductor manufacturing device and a method thereof capable of preventing a minute dust generated through a supporting roller from being penetrated into a process space of the semiconductor substrate, whereby decreasing the badness of the substrate.

Further anther object of the present invention is to provide a semiconductor manufacturing device and a method thereof capable of minutely controlling the revolution number of the susceptor.

Further anther object of the present invention is to provide a semiconductor manufacturing device and a method thereof capable of maintaining an airtight of a reaction chamber and preventing a heat transformation of a driving shaft.

Further anther object of the present invention is to provide a semiconductor manufacturing device and a method thereof capable of controlling a heating region in detail according to external conditions, whereby forming an uniform temperature gradient of the semiconductor substrate.

Further anther object of the present invention is to provide a semiconductor manufacturing device and a method thereof capable of allowing a moving of the heater and sufficiently maintaining the airtight of the reaction chamber.

Further anther object of the present invention is to provide a semiconductor manufacturing device and a method thereof capable of easily attaching and deattaching the heater.

To accomplish the objects, the present invention provides a semiconductor manufacturing device including a reaction chamber for providing an airtight process space; a boat including a pair of susceptors as the processing device mounted to the reaction chamber; a driving device for rotating the susceptors; a heater; a loading device for inserting the heater into an inner space of the susceptors; a supply nozzle and an exhaust nozzle; and a lifting device for inserting the exhaust nozzle into the space between the holders.

### BRIEF DESCRIPTION OF THE DRAWINGS

The above as well as the other objects, features and advantages of the present invention will be more apparent from the following detailed description taken in conjunction with the accompanying drawings, in which:

FIG. 1a is an explanatory view illustrating an external appearance of a semiconductor manufacturing device according to the present invention;

FIG. 1b is an explanatory view illustrating an arrangement status of a supply nozzle and an exhaust nozzle of the semiconductor manufacturing device according to the present invention;

FIG. 2a is an exploded perspective view illustrating a susceptor according to the present invention;

FIG. 2b and FIG. 2c are explanatory views illustrating the susceptor and a driving device connected to the susceptor according to the present invention;

FIG. 3a is an explanatory sectional view illustrating the semiconductor manufacturing device including the susceptor according to the present invention;

FIG. 3b is an enlarged sectional view of an upper portion of FIG. 3a;

FIGS. 4a and 4b are explanatory sectional views illustrating a driving device of the susceptor according to the present invention;

FIG. 4c is an explanatory view illustrating a cooling device of a driving shaft according to the present invention;

FIGS. 5a and 5b are explanatory sectional views illustrating a loading status of a heater according to the present invention;

FIG. 6a is an explanatory view illustrating a heating portion of the heater according to the present invention;

FIG. 6b is an explanatory view illustrating a heating pattern of the heater according to the present invention;

FIG. 6c is an explanatory view illustrating the semiconductor substrate and the nozzles arranged at the heating portion of the heater according to the present invention;

FIG. 7a is an explanatory view illustrating an exhaust nozzle according to the present invention;

FIG. 7b is an explanatory sectional view illustrating a lifting device according to the present invention; and

FIG. 7c is an explanatory sectional view illustrating a lifting of the exhaust nozzle, a connection of the susceptor, and an insertion of the heater according to the present invention.

### DETAILED DESCRIPTION OF THE PREFERRED EMBODIMENTS

A preferred embodiment of the invention will be described in detail below with reference to the accompanying drawings.

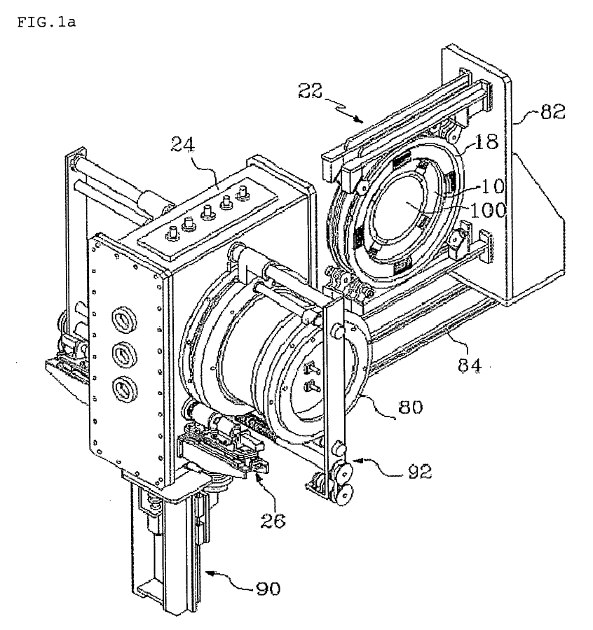

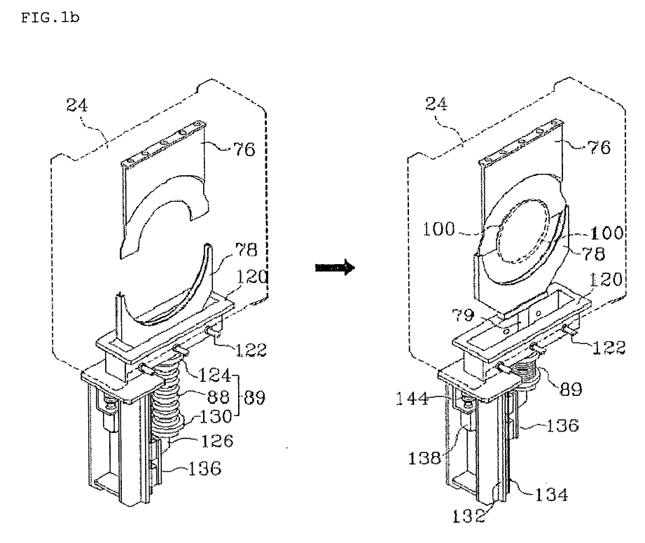

As shown in FIG. 1a through FIG. 7c, a semiconductor manufacturing device according to the present invention includes a reaction chamber 24 for providing an airtight process space; a boat 22 for putting in the reaction chamber 24 including a pair of susceptors 18 for elastically attaching a pair of holders 10 of a ring type thereto and mounting opposed semiconductor substrates 100 therein so as to perform a heat treatment in the direction of the back of the opposed semiconductor substrates 100 in the reaction chamber 24 and a plurality of support rollers 20 for rotating the susceptors 18; a driving device 26 for driving a pair of driving roller 20′ among the support rollers 20 and rotating the susceptors 18 after putting the boat 22 in the reaction chamber 24; a pair of heater 80 arranged at the back of the opposed semiconductor substrates 100 in order to perform the heat treatment of the semiconductor substrates 100 in the reaction chamber 24; a loading device 92 for inserting the heaters 80 into an inner space of the susceptors 18 after putting the boat 22 in the reaction chamber 24 and approaching each heating surface of the heaters 80 to the back of the opposed semiconductor substrates 100; a supply nozzle 76 for enveloping the upper portion of the opposed semiconductor substrates 100; an exhaust nozzle 78 for enveloping the lower portion of the opposed semiconductor substrates 100; and a lifting device 90 for waiting the exhaust nozzle 78 at the lower portion of the opposed semiconductor substrates 100 so as to evade the interference with the holder 10 prior to the loading/withdrawal of the reaction chamber 24 of the boat 22 and inserting the exhaust nozzle 78 between the holders 10 in order to envelope the lower portion of the opposed semiconductor substrates 100 next to the loading of the reaction chamber 24.

Each element of the susceptors 18 and the driving device 26 of the semiconductor device will be described in detail below (note FIG. 1 to FIG. 4).

Firstly, in each susceptor 18, a support panel 14 is mounted at the back of the holder 10 and elastically attached through an elastic attaching means 12 so as to support the semiconductor substrate 100 together with the holder 10 by contacting with the peripheral of the back of the semiconductor substrate 100.

Here, in each susceptor 18, an antifouling means is formed at the circumference of the susceptor 18 between the supporting roller 20 and the mounted semiconductor substrate 100 in order to prevent the penetration of an external particle in the direction of the mounted semiconductor substrate 100.

Concretely, the antifouling means includes an antifouling ring 30 protruded from the circumference of the susceptor 18 in the direction of the semiconductor substrate 100 in respect to the driving circumference portion 28 and the supporting rollers 20.

Moreover, a purge gas supplying portion 36 of the antifouling means for supplying a purge gas to a space between the opposed susceptors 18 is formed in the reaction chamber 24. Also, a gas curtain portion 34 is formed in the antifouling means.

Furthermore, another purge gas supplying portion 38 is formed at the reaction chamber 24 in order to supply the purge gas for disturbing the evaporation of the back of the semiconductor substrate 100 from the opposed susceptors 18 to the back of the semiconductor substrate 100.

Continuously, the driving device 26 includes a supporting frame 40 formed at the outside of the reaction chamber 24, a transferring panel 44 for sliding along a rail 42 formed at the supporting frame 40, a transferring device 46 for going and returning the transferring panel 44 formed at the supporting frame 40, a driving motor 50 having a driving shaft 48 for rotating the driving roller 20′ formed at the transferring panel 44, and a connecting means 52 connected to the driving shaft 48.

More concretely, the transferring device 46 includes a transferring motor 54 formed at the supporting frame 40, a transferring bolt 56 as a driving shaft connected to the transferring motor 54, a transferring nut 58 coupled to the transferring bolt 56, and a supporting rod 60 coupled to the transferring nut 58 together with a buffer spring 61 and coupled to the transferring panel 44.

The driving shaft 48 is spline-coupled to the connection means 52. Here, a guide tapper surface 62 for inducing the spline-couple is formed at a front end of driving shaft 48.

In the meantime, the driving shaft 48 is penetrated through the reaction chamber 24. Here, in order to maintain an airtight between the driving shaft 48 and the reaction chamber 24, a reaction chamber mounting ring 64 is formed at a through hole of the reaction chamber 24, a sealing means 66 for sealing the outer circumference of the driving shaft 48 is separated from the reaction chamber 24, and bellows tube 68 for maintaining the moving of the driving shaft 48 and sealing the outer circumference of the driving shaft 48 between the sealing means 66 and the reaction chamber mounting ring 64.

Also, the driving shaft 48 is made of an insulating material so as to prevent a heat from transmitting to the driving motor 50 and is spline-coupled to the rotating shaft of the driving motor 50 through a coupler 72.

Moreover, the driving shaft 48 includes a cooling device. The cooling device includes a cooling waterway 74 and a cooling water connector 75 of a ring type for supplying and discharging the cooling water to the cooling waterway 74 of the rotated driving shaft 48 formed at the gateway of the cooling waterway 74.

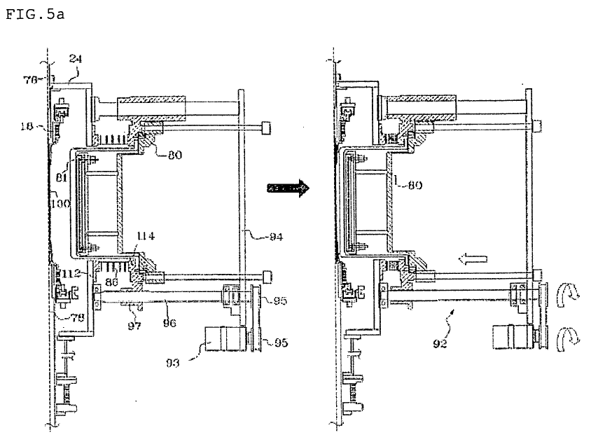

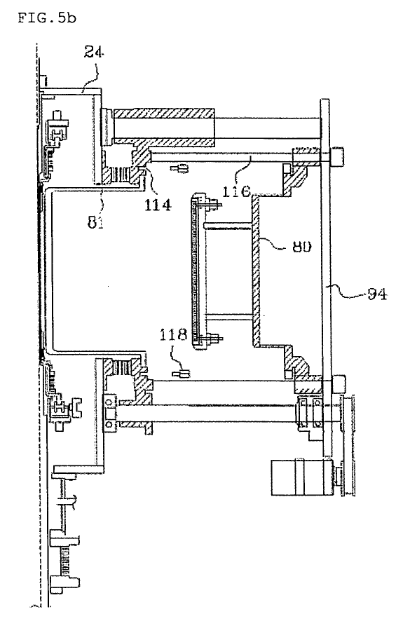

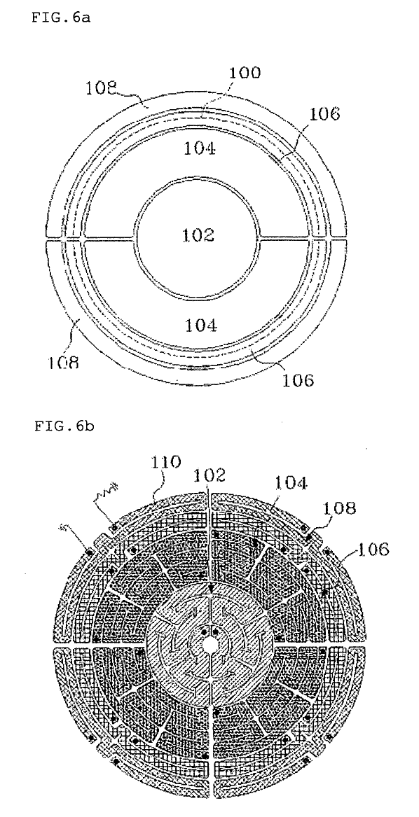

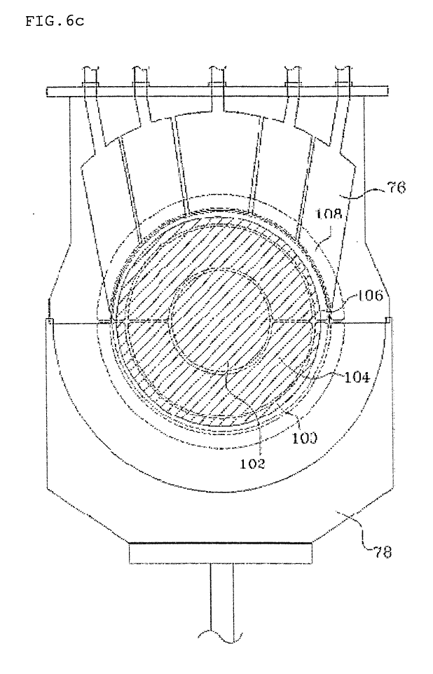

Each element of the heater 80 including the mounting device of the semiconductor device will be described in detail below (note FIG. 1, FIG. 5 and FIG. 6).

Firstly, in order to heat the opposed semiconductor substrates 100 in the direction of the back of each semiconductor substrates, the heater 80 has a heating surface for receiving the whole area of the semiconductor substrates 100. Also, the heating region provided by the heating surface has a separated power supplying line and is concentric to the semiconductor substrates 100. The heating region includes a central portion 102 for heating the center of the semiconductor substrates 100, a peripheral portion 104 for heating the outside of the center of the semiconductor substrates 100 and surrounding the central portion 102, an outer circumference portion 106 for heating the outer circumference of the semiconductor substrates 100 and surrounding the peripheral portion 104, and a buffer portion 108 surrounding the outer circumference portion 106 and for heating it so as to alleviate the interference between the outer circumference portion 106 and the room temperature.

Concretely, the peripheral portion 104, the outer circumference portion 106 and the buffer portion 108 divide into at two vertical partitions corresponding to the upper and lower portions of the semiconductor substrates 100 respectively.

The upper portion of the buffer portion 108 connected to the gateway of the supply nozzle 76 of the reaction gas serves to preheat the reaction gas prior to injecting it.

The upper portion of the outer circumference portion 106 corresponding to the gateway of the supply nozzle 76 of the reaction gas and the space between the semiconductor substrates 100 serves to heat the reaction gas supplied to the semiconductor substrates 100 next to injecting it.

In the meantime, the heating region of the heater 80 further includes a plurality of winding resistance heating lines 110 having a supplying line and a grounding line adjacent to each other.

The heater 80 further includes a loading device 92 inserted into the back of the semiconductor substrates 100 mounted to the susceptors 18 after mounting the susceptors 18 to the reaction chamber and the heater 80 is hermetically mounted to the reaction chamber 24 by means of a bellows cover 87.

Concretely, the bellows cover 87 includes a reaction chamber mounting ring 112 surrounding the circumference of a through hole of the reaction chamber 24 in order to load the heater 80, a heater mounting ring 114 combined with the loading device 92 inserted into the back of the semiconductor substrates 100, a bellows tube 86 for sealing the space between the reaction chamber mounting ring 112 and the heat mounting ring 114 and allowing the moving thereof through the loading device 92, a guide rail 116 for attaching and deattaching the heater 80 formed at the heater mounting ring 114. Here, the heater 80 is slid along the guide rail 116 and coupled to the heater mounting ring 114.

Also, the heater 80 further includes a heater cover 81 for maintaining the airtight between the heater 80 and the reaction chamber 24. The heater cover 81 is a transparent cover such as a quartz cover and so on. The outer circumference of the heater cover 81 is inserted between the heat mounting ring 114 and the heater 80 in order to maintain the airtight between the heater 80 and the reaction chamber 24.

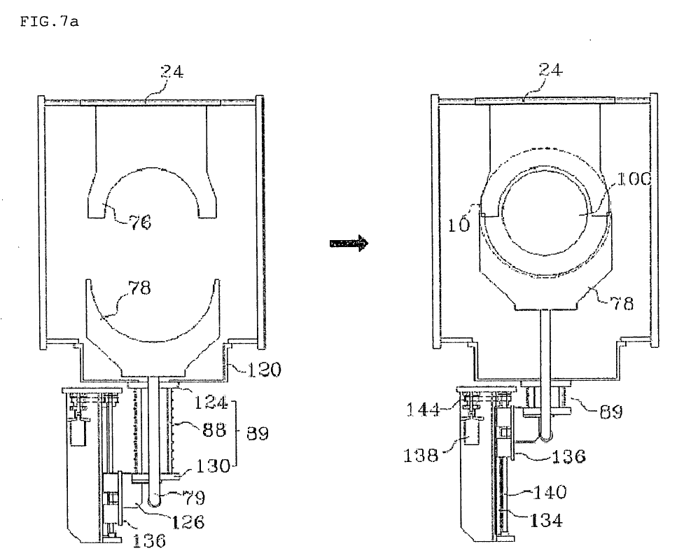

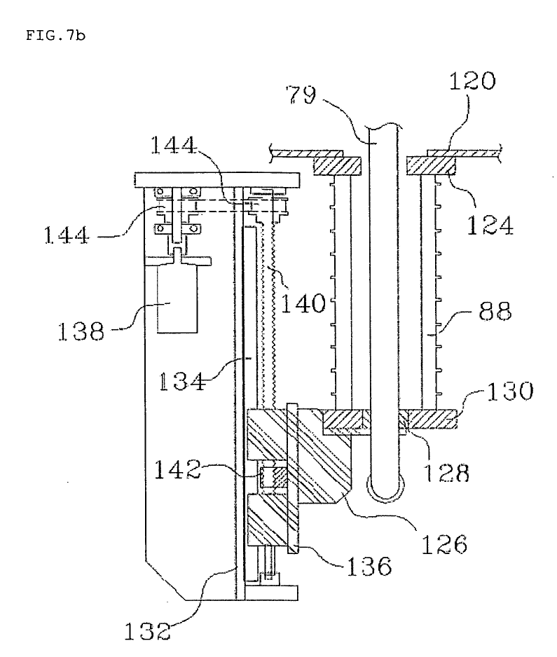

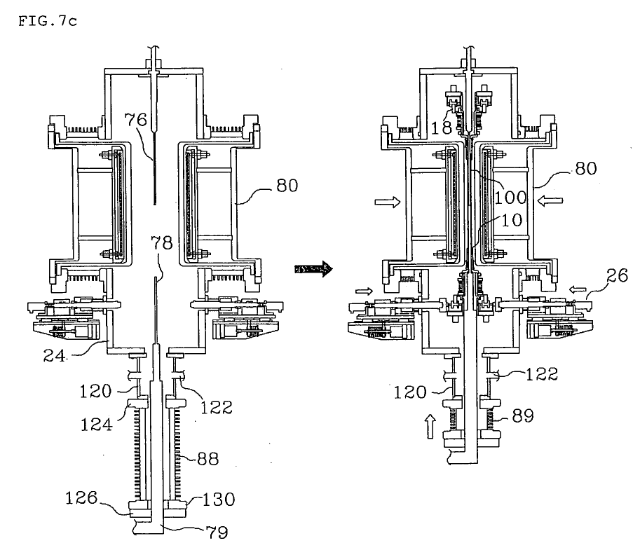

Each element of the exhaust nozzle 78 including the lifting device 90 of the semiconductor device will be described in detail below (note FIG. 1 and FIG. 7).

Firstly, the exhaust nozzle 78 separately mounted to the reaction chamber 24 includes an exhaust pipe 79 penetrated through the reaction chamber 24 and formed at the outside thereof and a bellows cover 89 for maintaining the moving of the exhaust pipe 79 and performing the airtight thereof formed between the exhaust pipe 79 and the reaction chamber 24.

Concretely, the bellows cover 89 of the exhaust nozzle 78 includes a reaction chamber mounting ring 124 surrounding the circumference of a through hole of the reaction chamber 24 for arrangement of the exhaust pipe 79 of the exhaust nozzle 78, a bracket mounting ring 130 mounted to a coupling bracket 126 of the lifting device 90 for lifting the exhaust nozzle 78 and having a packing 128 for sealing the outer circumference of the exhaust pipe 79, and a bellows tube 88 for sealing the space between the reaction chamber mounting ring 124 and the bracket mounting ring 130 and allowing the lifting of the exhaust pipe 79 through the loading device 92.

In the meantime, the lifting device 90 includes a supporting frame 132 formed at the outside of the reaction chamber 24, a lifting panel 136 for sliding along a rail 134 formed at the supporting frame 132, the coupling bracket 126 mounted to the lifting panel 136 and coupled to the exhaust pipe 79 of the exhaust nozzle 78, a lifting motor 138 formed at the supporting frame 132, a lifting bolt 140 as a driving shaft connected to the lifting motor 138, a lifting nut 142 coupled to and lifted up and down the lifting bolt 140 and combined with the lifting panel 136.

Here, the standby chamber 120 for standing by the exhaust nozzle 78 is formed at the lower portion of the reaction chamber 24.

Also, a purge exhaust pipe 122 for removing the purge gas is connected to the standby chamber 120.

A semiconductor manufacturing method for processing the opposed semiconductor substrates 100 according to the present invention will be described in detail below.

The semiconductor manufacturing method for processing the opposed semiconductor substrates according to the present invention includes the steps of loading a pair of the opposed semiconductor substrates on the reaction chamber for providing an airtight process space, connecting the driving shaft to a pair of driving roller among the support rollers of the susceptors in order to process the opposed semiconductor substrates, approaching the heating surface of the heater to the back of the semiconductor substrates, inserting the exhaust nozzle for surrounding the lower portion of the semiconductor substrate into the space between the opposed holders, and processing the opposed semiconductor substrates.

Here, in the processing device loading step, the driving shaft connected to the driving roller, the heater moved toward the back of the semiconductor substrate, and the exhaust nozzle inserted into the space between the opposed holders maintain the moving and the airtight thereof respectively.

In the meantime, the processing step further includes a back side evaporation disturbing step for disturbing the evaporation of the back of the semiconductor substrate by supplying the purge gas to each back side of the opposed semiconductor substrates.

Also, the processing step further includes an antifouling step for preventing the penetration of the minute dust in the direction of the inside of the opposed susceptors 18 by supplying the purge gas to the outer circumference of the each semiconductor substrate and forming the gas curtain portion 34 between each susceptor and the supporting rollers located at the circumference of each susceptor.

Also, the processing step further includes a heat treating step for heating the opposed semiconductor substrates 100 in the direction of the back of each semiconductor substrates through the heater 80 having the heating surface for receiving the whole area of the semiconductor substrates 100. Here, the heating region concentric to the semiconductor substrates includes a central portion 102 for heating the center of the semiconductor substrates 100, a peripheral portion 104 for heating the outside of the center of the semiconductor substrates 100 and surrounding the central portion 102, an outer circumference portion 106 for heating the outer circumference of the semiconductor substrates 100 and surrounding the peripheral portion 104, and a buffer portion 108 surrounding the outer circumference portion 106 and for heating it so as to alleviate the interference between the outer circumference portion 106 and the room temperature. Here, the peripheral portion 104, the outer circumference portion 106 and the buffer portion 108 divide into at least two vertical partitions corresponding to the upper and lower portions of the semiconductor substrates 100 respectively.

The upper portion of the buffer portion 108 connected to the gateway of the supply nozzle 76 of the reaction gas allows the reaction gas to preheat and then, the preheated gas is injected.

The upper portion of the outer circumference portion 106 corresponding to the gateway of the supply nozzle 76 of the reaction gas and the space between the semiconductor substrates 100 allows the injected gas to heat and then, the heated gas is supplied to the semiconductor substrates 100.

As described above, the semiconductor manufacturing device according to the present invention includes a reaction chamber 24 for providing an airtight process space; a boat 22 including a pair of susceptors 18 as the processing device mounted to the reaction chamber; a driving device 26 for rotating the susceptors 18; the heater 80; the loading device 92 for inserting the heaters 80 into an inner space of the susceptors 18; the supply nozzle 76 and the exhaust nozzle 78; and the lifting device 90 for inserting the exhaust nozzle 78 into the space between the holders 10.

Each element of the semiconductor device according to the present invention will be more minutely described below.

Firstly, as shown in FIG. 1, the reaction chamber 24 for providing an airtight process space is provided. The reaction chamber 24 includes the opposed semiconductor substrates 100, a pair of susceptors 18 for supporting the semiconductor substrates 100, the boat 22 having the susceptors 18. Here, the reaction chamber has a size capable of receiving the boat 22.

The reaction gas is flowed from the upper portion toward the lower portion of the reaction chamber 24. H ere, the supply nozzle 76 is formed at the upper portion thereof and the exhaust nozzle 78 is formed at the lower portion thereof.

The heater 80 for providing the high temperature and the driving device 26 connected to the driving rolloers 20′ of the susceptors 18 are formed at both sides of the reaction chamber 24.

The boat includes a boat cap 82 for blocking the rear of the susceptors 18 and providing an airtight process space. Here, the boat cap 82 is mounted on a moving rail 84.

The semiconductor substrate 100 is loaded on the holder 10 of the boat 22 by means of an end-effector (not shown) and then, the holder 10 is loaded on the susceptors by means of the end-effector.

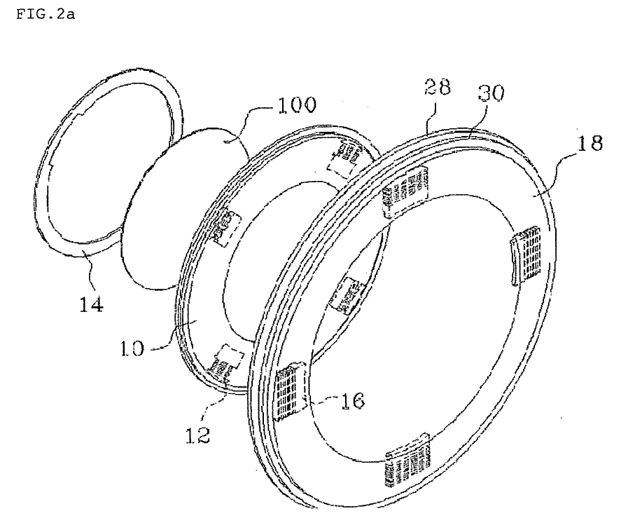

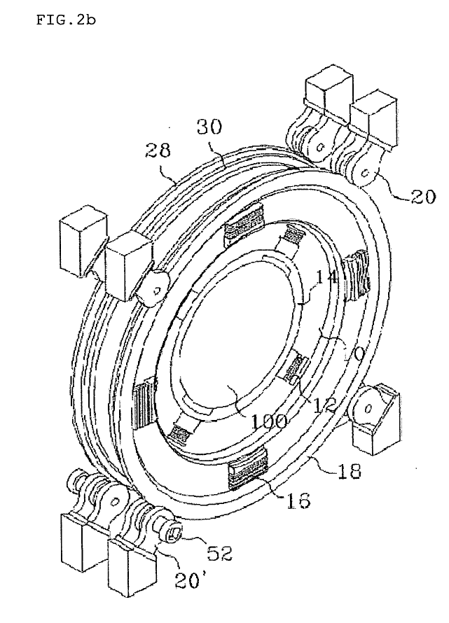

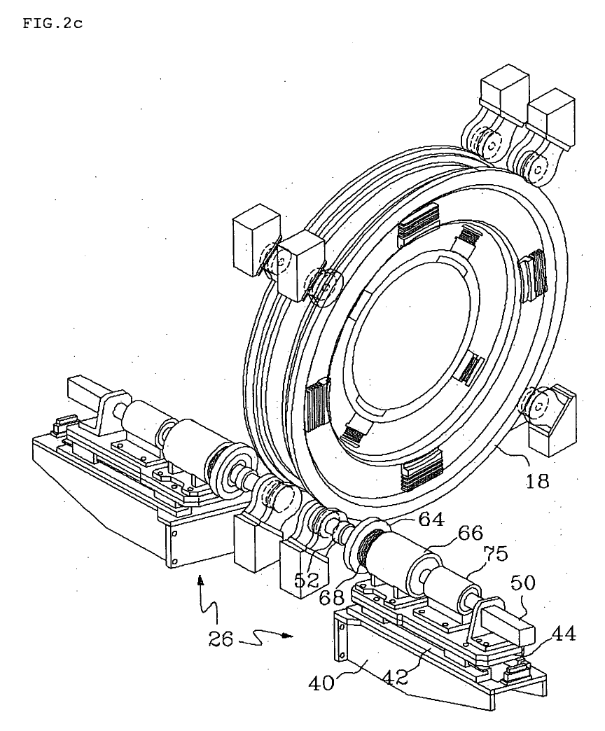

As shown in FIG. 2 through FIG. 4, the susceptors 18 including the holder 10 divides into the susceptors 18, the holder 10 and the supporting panel 14. The holder 10 is elastically attached to the susceptors 18 through an elastic attaching means 16. The holder 10 holds the semiconductor substrate 100 through the elastic attaching means 12 and the supporting panel 14. Also, the antifouling means is formed at the circumference of the susceptor 18.

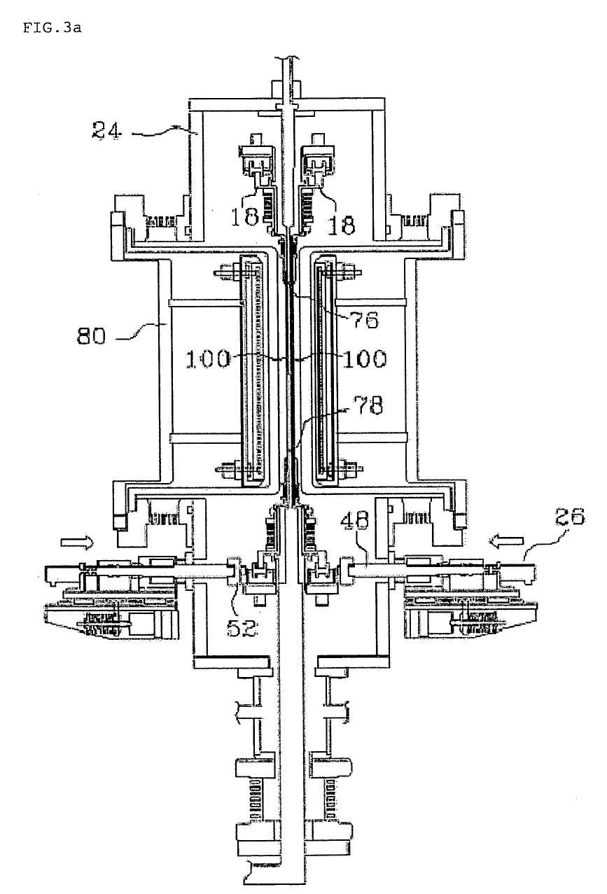

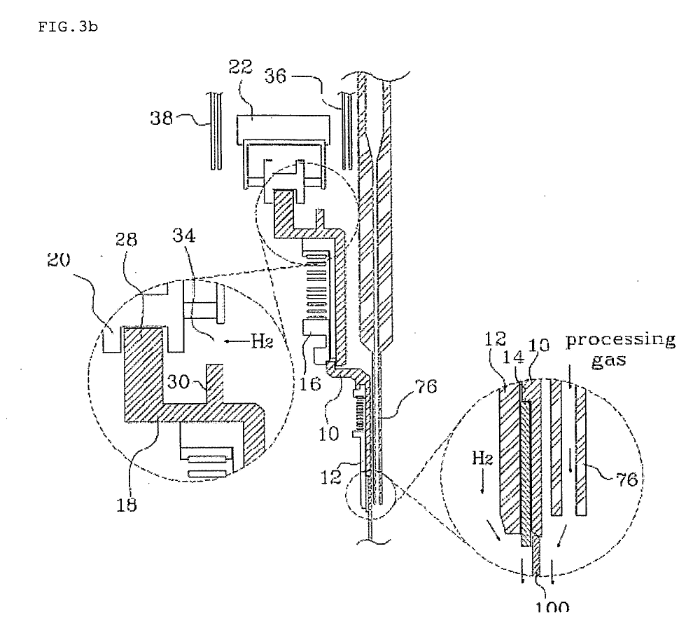

More concretely, as shown in FIG. 2 and FIG. 3, the holder 10 of the ring type is open to the front side of the semiconductor substrate 100 in such a manner that the perimeter end of the frond side of the semiconductor substrate 100 is slightly interfered with the holder 10. Also, the supporting panel 14 of the ring type is elastically attached to the holder 10 by means of the elastic attaching means 12 in such a manner that the perimeter end of the back of the semiconductor substrate 100 is slightly interfered with the supporting panel 14. Accordingly, the semiconductor substrate 100 is not pressurized by the elastic attaching means.

The susceptor 18 is in the shape of a convex dish in front in order to closely face the loaded semiconductor substrates 100. Here, the driving circumference portion 28 located at the outer circumference of the susceptor 18 and contacted with the supporting roller 20 is protruded.

The antifouling means for preventing the penetration of the minute dust surroundings the outer circumference of the susceptor 18 in the direction of the semiconductor substrate 100 in respect to the supporting rollers 20.

Here, the antifouling means includes the antifouling ring 30 protruded from the circumference of the susceptor 18 between the driving circumference portion 28 contacted with the supporting rollers 20 and the mounted semiconductor substrate 100.

That is, the antifouling ring 30 serves as a protrusion structure capable of coping with the penetration (penetration direction) of the minute dust.

Moreover, the purge gas supplying portion 36 of the antifouling means for supplying a purge gas to a space between the opposed susceptors 18 is formed in the reaction chamber 24. Also, a gas curtain portion 34 is formed in the antifouling means.

Furthermore, another purge gas supplying portion 38 is formed at the reaction chamber 24 in order to supply the purge gas for disturbing the evaporation of the back of the semiconductor substrate 100 from the opposed susceptors 18 to the back of the semiconductor substrate 100.

In order to form the gas curtain portion 34, the purge gas supplying portion is formed at the reaction chamber 24. Here, the kind of the purge gas is H₂.

The purge gas injected into the reaction chamber 24 is discharged through the purge exhaust pipe 122 formed at the standby chamber 120.

In the meantime, where the semiconductor substrates 100 are loaded on the susceptors 18, the semiconductor substrates 100 keep standing and are opposed to each other. Here, the susceptors 18 can be rotated through the supporting rollers 20.

As shown in FIG. 2b, any one of the supporting roller 20 includes the connecting means 52 having a spline groove for connecting to the driving shaft 48 of the driving device 26.

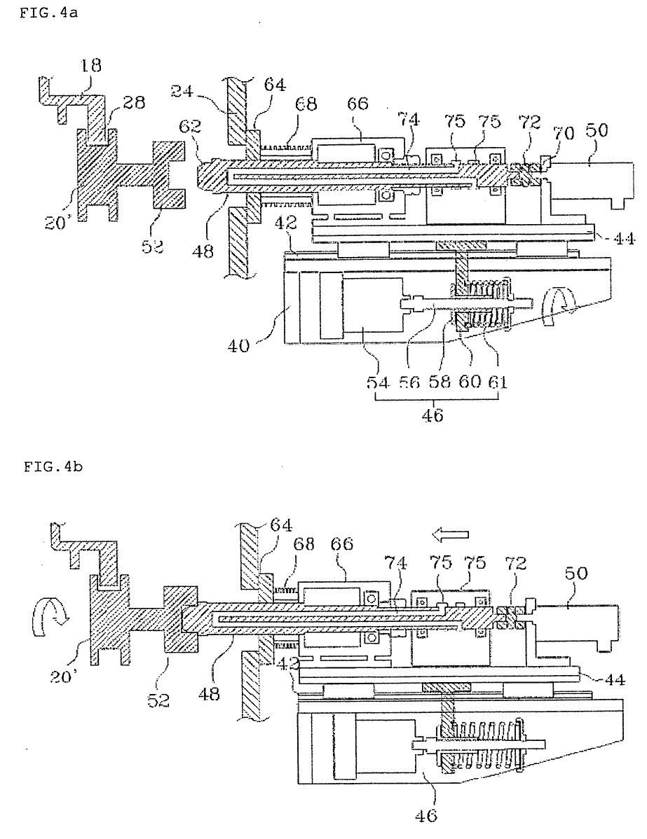

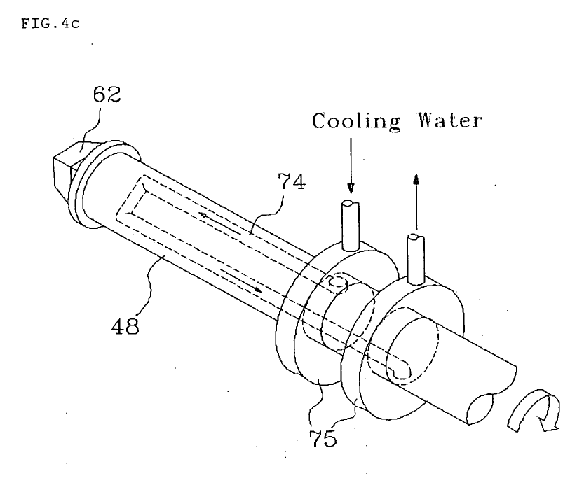

The boat 22 is loaded on the reaction chamber 24 through the connecting means 52 and the driving device 26 is transferred, so that the connection is performed as shown in FIG. 2c, FIG. 4a and FIG. 4b.

At this time, the susceptors driving device 26 is isolated with the reaction chamber 24 through a bellows cover 69. That is, since the explosive purge gas such as the H₂ gas is introduced, it is necessary to prevent the purge gas from being flowing out the reaction chamber 24. Also, in order to provide a low pressure (a vacuum) environment for treating the process thereof and prevent the outflow of the poison gas during processing thereof, it is necessary to seal it.

More concretely, the driving device 26 includes the supporting frame 40 formed at the outside of the reaction chamber 24 and the transferring panel 44 for sliding along the rail 42 formed at the supporting frame 40.

Also, the driving device 26 further includes the transferring device 46 for going and returning the transferring panel 44 formed at the supporting frame 40, the driving motor 50 having the driving shaft 48 for rotating the driving roller 20′ formed at the transferring panel 44, and the connecting means 52 connected to the driving shaft 48.

Here, in order to penetrate through the reaction chamber 24 and maintain the airtight between the driving shaft 48 and the reaction chamber 24, the reaction chamber mounting ring 64 is formed at the through hole of the reaction chamber 24, in that the driving shaft 48 is penetrated and moved and the sealing means 66 for sealing the outer circumference of the driving shaft 48 is separated from the reaction chamber 24.

The sealing means 66 for sealing the airtight of the rotating driving shaft 48 is made of a magnetic shield.

Also, the bellows tube 68 for maintaining the moving of the driving shaft 48 and sealing the outer circumference of the driving shaft 48 through the sealing means 66 is formed between the reaction chamber mounting ring 64.

Moreover, the transferring device 46 for moving the transferring panel 44 having the above devices includes the transferring motor 54 formed at the supporting frame 40, the transferring bolt 56 as the driving shaft connected to the transferring motor 54, and the transferring nut 58 for transforming the rotary motion into the rectilineal movement and performing the reciprocating motion coupled to the transferring bolt 56.

Furthermore, the supporting rod 60 is coupled to the transferring nut 58 together with the buffer spring 61. Here, the buffer spring 61 allows the supporting rod 60 to be elastically attached to the transferring nut 58 through the spring sheet. Accordingly, the supporting rod 60 and the transferring panel 44 are coupled to each other so at to complete the transferring device.

Here, in order to alleviate the connection tolerance or the connection impact on the moving the driving shaft 48, the transferring nut 58 is separated from the supporting rod 60 and the supporting rod 60 is elastically attached backward through the buffer spring 61. That is, during the connection of the driving shaft 48, as though the front end thereof is moved beyond the connection limit, the supporting rod 60 is retreated backward in that degree. At this time, the buffer spring 61 allows the gap moving of the supporting rod 60 to some degree and elastically supports the supporting rod 60.

The driving shaft 48 is spline-coupled to the connection means 52. Here, the guide tapper surface 62 for inducing the spline-couple is formed at the front end of driving shaft 48.

In the spline-coupling of the driving shaft 48 and the connection means 52, as though the groove and the protrusion of the driving shaft 48 and the connection means 52 are accurately not accorded with each other during the first connection thereof, they can be accorded with each other by the combination of the inducing slanting surface at the point of the completion time.

As shown in FIG. 2b, the spline is in the form of a square. However, the invention is not limited to the shape of the spline. Of course, the spline may be a polygonal shape or a curved shape.

The airtight is maintained by means of the susceptors driving device 26 connected to the connecting means 52 thereof, so that the minute control of the rotational frequency can be carried out according to the driving device directly connected to each susceptor.

Here, an amount of the heat can be transmitted to the driving shaft according to the driving of the susceptor 18 (for example, a process of high-temperature such as an epitaxial process). At this time, the magnetic force of the driving motor can be damaged owing to the heat transmitted to the driving shaft.

After all, it is necessary to prevent the heat from transmitting to the driving shaft and protect the damage of the heat of the driving shaft.

For this reason, the driving shaft 48 is made of an insulating material between the rotating shaft 70 of the driving motor 50 and spline-coupled to the rotating shaft of the driving motor 50 through the coupler 72.

Moreover, the driving shaft 48 includes the cooling device. The cooling device includes the cooling waterway 74 and the cooling water connector 75 of the ring type for supplying and discharging the cooling water to the cooling waterway 74 of the rotated driving shaft 48 formed at the gateway of the cooling waterway 74 (note FIG. 4).

The cooling waterway 74 of the rotated driving shaft 48 has an entrance and an exit in that the cooling water connector 75 is formed.

The cooling water connector 75 includes a sealing portion (not shown) for sealing the outer circumference of the driving shaft 48. Also, since a connecting space connected to any of the entrance and the exit of the cooling waterway 74 is provided, as though the driving shaft is rotated, the cooling water connector 75 can be connected to the entrance and the exit of the cooling waterway 74 in order to supply and discharge the cooling water.

The cooling water supplied to the cooling waterway 74 allows the heat of the driving shaft to be cooled, thereby preventing a heat damage (a heat transformation) of the driving shaft.

Each element of the heater 80 including the loading device of the semiconductor device will be more minutely described with reference to FIG. 1, FIG. 5 and FIG. 6).

As shown in the drawings, each susceptor 18 is formed at boat 22 in such a manner that they are contacted with the supporting rollers 20 to be rotated. Also, the susceptor 18 is in the shape of a convex dish in front in order to closely face the loaded semiconductor substrates 100 inside the contact lines of the supporting rollers 20.

In the meantime, where the semiconductor substrates 100 are loaded on the susceptors 18, the semiconductor substrates 100 keep standing and are opposed to each other. Here, the susceptors 18 can be rotated through the supporting rollers 20 as described above.

At this time, the heater 80 is waiting for at the outside of the susceptors 18. After the completion of the loading, the heater 80 is inserted into a concave groove of the susceptors 18 and loaded closely to the back of the semiconductor substrates 100.

In order to allow the moving of the heater 80 through the loading device 92 and ensure the airtight of the reaction chamber 24, the heater 80 is separated from the reaction chamber 24 and is hermetically mounted to the reaction chamber 24 by means of the bellows cover 87.

Concretely, the bellows cover 87 includes a reaction chamber mounting ring 112 surrounding the circumference of the through hole of the reaction chamber 24 and the heater mounting ring 114 combined with the heater 80 and the loading device 92.

Also, the bellows tube 86 for sealing the space between the reaction chamber mounting ring 112 and the heat mounting ring 114 and allowing the moving thereof through the loading device 92 is formed.

Here, a transferring motor 93 for generating a driving force is formed at the a supporting frame 94 and a pair of pulleys 95 for transmitting the driving force of the transferring motor 93 is formed at the supporting frame 94. Here, any one pulley 98 is connected to the rotating shaft of the transferring motor 93.

Also, another pulley 98 is connected to the one end of a transferring bolt 96 and another end of the transferring bolt 96 is rotably mounted to the reaction chamber 24.

A transferring nut 97 for performing a pitch moving (a rectilineal moving) according to the rotation of the transferring bolt 96 is interlocked with and fixed to the transferring bolt 96 by a screw. Here, the transferring nut 97 is integrally connected to the heater mounting ring 114 and the heater mounting ring 114 is combined with the heater 80, so that the heat mounting ring 114 and the heater 80 are transferred together with the transferring nut 97, thereby the heater 80 can be loaded toward the back of the semiconductor substrate 100 located at the inside of the reaction chamber 24.

In the meantime, the guide rail 116 for attaching and deattaching the heater 80 is formed at the heater mounting ring 114. Here, the heater 80 is slid along the guide rail 116 and coupled to the heater mounting ring 114.

Also, the outer circumference of the heater cover 81 is inserted between the heat mounting ring 114 and the heater 80 in order to attach and deattach the heat cover to the heater body.

The heater cover 81 is a transparent cover such as a quartz cover and so on. The heater cover 81 is inserted between the heat mounting ring 114 and the heater 80 in order to maintain the airtight between the heater 80 and the reaction chamber 24.

Accordingly, where the coupling means 118 for connecting the heater 80 to the heater mounting ring 114 is removed to release the connection thereof, the body of the heater 80 can be easily removed along the guide rail 116.

After the heater 80 is loaded on the reaction chamber 24, the susceptors 18 is rotated in order to progress the process. Then, the reaction gas is injected and discharged between the opposed semiconductor substrate 100. At this time, it produces a high-temperature environment by means of the heater 80.

In order to form the film on the reaction surface of the semiconductor substrate 100, it is necessary to generate an appropriate temperature gradient on the semiconductor substrate 100. Therefore, the heater 80 has the heating surface for receiving the whole area of the semiconductor substrates 100 in order to heat the opposed semiconductor substrates 100 in the direction of the back of each semiconductor substrates. As described above, the heating region includes the central portion 102, the peripheral portion 104, the outer circumference portion 106, and the buffer portion 108 (note FIG. 6).

The divided portions have separate power supply lines and different heating temperatures respectively. The remaining portions except for the central portion 102 divide into at least two separate portions vertically.

As shown in FIG. 6a, the divided portions have at least seven portions. That is, the divided portions the central portion 102, two peripheral portions 104 surrounding the central portion 102, two outer circumference portions 106 surrounding the peripheral portions 104, and two buffer portions 108 surrounding the outer circumference portions 106.

In the meantime, as shown in FIG. 6b, the heating surface (heating pattern) divides into four divided areas. However, the invention is not limited to the number of the divided area. Accordingly, it is possible to minutely control the semiconductor substrate. Especially, where one divided area corresponds to a heat unit, the damaged heat unit can be easily changed, thereby deriving a benefit of the material.

More concretely, the central portion 102 is concentric to the semiconductor substrates 100. That is, the central portion 102 corresponds to a circle area having a half diameter of each semiconductor substrate 100. The central portion 102 heats each semiconductor substrate 100 at the same temperature as the conventional heater.

The peripheral portion 104 surrounds the central portion 102 and heats the outside of the central portion 102. The peripheral portion 104 divides into at least two vertical partitions corresponding to the upper and lower portions of the semiconductor substrates 100.

More concretely, the peripheral portion 104 corresponds to an area from the boundary of the central portion 102 to the inside region adjacent to the peripheral of the semiconductor substrate 100. In the initial stage of the reaction gas injection, since the temperature of the peripheral area of the upper portion (a half circle) of the semiconductor substrate 100 can be lower than that of the lower part thereof, the peripheral area of the upper portion of the semiconductor substrate 100 can be highly heated.

The outer circumference portion 106 surrounds the peripheral portion 104 at the outside of the peripheral portion 104. The outer circumference portion 106 heats the area including the peripheral of the semiconductor substrate 100.

Concretely, the outer circumference portion 106 divides into at least two vertical partitions corresponding to the upper and lower portions of the semiconductor substrates 100. The outer circumference portion 106 includes the peripheral area of the semiconductor substrate 100 as well as the inside and outside areas of the peripheral line of the semiconductor substrate 100. Especially, the outer circumference portion 106 can compensate the drop of the temperature of the peripheral area of the semiconductor substrate 100.

Here, after the first supplied reaction gas is heated and the reaction gas supplied to the semiconductor substrate 100 is injected, the upper portion of the outer circumference portion 106 serves as a heating area (note FIG. 6c).

That is, when the reaction gas is injected into the semiconductor substrate 100, the outer circumference portion 106 prevent the process temperature of the semiconductor substrate 100 from being lower at the first reaction area owing to the temperature of the reaction gas.

Continuously, the buffer portion 108 surrounds the outer circumference portion 106 and heats it so as to alleviate the interference between the outer circumference portion 106 and the room temperature.

Concretely, the buffer portion 108 divides into at least two vertical partitions corresponding to the upper and lower portions of the semiconductor substrates 100. The buffer portion 108 serves to alleviate the unevenness of the temperature gradient generated from the interference between the outer circumference portion 106 and the room temperature.

That is, the outer circumference portion 106 is extended to the outside of the peripheral area of the semiconductor substrate 100. However, the temperature drop of the peripheral (edge) portion of the semiconductor substrate 100 cannot be sufficiently prevented by means of the outer circumference portion 106. Accordingly, The buffer portion 108 serves to alleviate the direct interference between the outer circumference portion 106 and the room temperature.

Especially, the upper portion of the buffer portion 108 connected to the gateway of the supply nozzle 76 of the reaction gas serves to preheat the reaction gas just prior to injecting it (note FIG. 6c).

Accordingly, the upper portion of the buffer portion 108 is the preheated area of the reaction prior to injecting it. The reaction gas preheated by the buffer portion 108 is injected, and then is secondary-heated at the outer circumference portion 106 to being putted in the semiconductor substrates 100.

The heating region according to the present invention allows the temperature gradient produced on the semiconductor substrate 100 to be more uniformly against the external disturbances (the temperature of the reaction gas and the interference with the room temperature).

In the meantime, the heating region of the heater 80 further includes the plurality of winding resistance heating lines 110 adjacent to each other in order to take charge of the corresponding divided portions, respectively (note FIG. 6b).

The indicated lines shown in FIG. 6b illustrate the supplying line and the grounding line. Also, the power line is connected to the rear of the heating surface.

Here, the power line is electrically connected to the supplying line and the grounding line.

Accordingly, each divided portion of the heating region is separately provided with the resistance heating lines 110 and the winding resistance heating lines 110 fill the area of each corresponding divided portion, thereby form the separate heating surfaces.

Each element of the exhaust nozzle 78 including the lifting device 90 of the semiconductor device will be more minutely described with reference to FIG. 1 and FIG. 7.

As described above, each susceptor 18 is formed at boat 22 in such a manner that they are contacted with the supporting rollers 20 to be rotated. Also, the susceptor 18 is in the shape of a convex dish in front in order to closely face the loaded semiconductor substrates 100 inside the contact lines of the supporting rollers 20.

The reaction gas is flowed from the upper portion toward the lower portion of the reaction chamber 24. H ere, the supply nozzle 76 is formed at the upper portion thereof and the exhaust nozzle 78 is formed at the lower portion thereof (note FIG. 1b).

Here, since the supply nozzle 76 has a thin thickness enough to escape the interference with the holder 10 during the loading and releasing of the boat 22, it may be fixed to the reaction chamber 24.

In the meantime, the exhaust nozzle 78 is separated from the supply nozzle 76 and is separately provided with the boat 22. Accordingly, The exhaust nozzle 78 is waiting for in order to escape the interference with the boat 22 prior to the loading and releasing of the boat 22.

The exhaust nozzle 78 requires a suction portion (space) in order to collect the reaction gas differently with the supply nozzle 76. That is, the exhaust nozzle 78 is maximally close between the opposed holders 10 in order to collect the reaction gas.

Here, since the moving range of the boat 22 is large, it is not desirable that the boat 22 is provided together with the exhaust nozzle 78 and its peripheral device.

At this time, in a case that the exhaust nozzle 78 is fixed to the reaction chamber 24, it can be rubbed with the holders 10 (between the holders 10) on the moving path of the boat 22. Also, the friction brings about a minute dust, thereby contaminating the process space.

Accordingly, the lifting device 90 is formed at the exhaust nozzle 78 in order to stand by at the lower portion of the opposed holder 10 prior to the loading/withdrawal of the reaction chamber 24 and load the of the exhaust nozzle 78 between the holders 10 during the loading thereof.

Concretely, the exhaust nozzle 78 is arranged in the form of a semicircle between the holders 10 in order to surround the lower portion of the opposed semiconductor substrate. During the standing by of the exhaust nozzle 78, the exhaust nozzle 78 is formed at the reaction chamber 24 in such a manner that both ends of the exhaust nozzle 78 are vertically separated from the holders 10.

Here, the separation of the exhaust nozzle 78 means the separation with the circumference boundary of each holder 10 at the space between the holders 10.

Also, the standby chamber 120 for standing by the exhaust nozzle 78 is formed at the lower portion of the reaction chamber 24.

The standby chamber 120 receives the proper portion of the exhaust nozzle 78. Also, during the process thereof, the purge gas is collects by the standby chamber 120 separately fixed to the reaction chamber 24.

In the meantime, the lifting device 90 is formed at the lower portion of the reaction chamber 24 and the bellows cover 89 and the exhaust nozzle 78 are connected to the lifting device 90.

Concretely, the bellows cover 89, which is a part of the reaction chamber 24 for arrangement of the exhaust pipe 79 includes the reaction chamber mounting ring 124 surrounding the circumference of the through hole of the reaction chamber 24 and the bracket mounting ring 130 mounted to the coupling bracket 126 of the lifting device 90 for lifting the exhaust nozzle 78 and having the packing 128 for sealing the outer circumference of the exhaust pipe 79.

The bellows cover 89 further includes the bellows tube 88 for sealing the space between the reaction chamber mounting ring 124 and the bracket mounting ring 130 and allowing the lifting of the exhaust pipe 79 through the lifting device 92.

Also, the lifting device 90 includes the supporting frame 132 formed at the outside of the reaction chamber 24 and the lifting panel 136 for sliding along the rail 134 formed at the supporting frame 132.

Moreover, the lifting device 90 includes the coupling bracket 126 mounted to the lifting panel 136 and coupled to the exhaust pipe 79 of the exhaust nozzle 78 and the bracket mounting ring 130.

In the meantime, the lifting motor 138 is formed at the supporting frame 132 and the lifting bolt 140 as the driving shaft is connected to the lifting motor 138. Here, the lifting bolt 140 receives the driving force from the lifting motor 138 by means of a pulley 144.

The lifting nut 142 for performing the pitch moving (rectilineal moving) according to the rotation of the lifting bolt 140 is interlocked with and fixed to the lifting bolt 140 by a screw. Here, the lifting nut 142 is integrally connected to the lifting panel 136.

Accordingly, the standby status of the exhaust nozzle 79 is maintained at the lower portion thereof prior to loading the semiconductor substrate 100 on the reaction chamber 21 or the withdrawal of the reaction chamber 24, so as to maintain the standby status thereof.

Here, the bellows cover 89 surrounds the outer circumference of the exhaust pipe 79 and maintains its tensile status.

Continuously, after loading the semiconductor substrate 100 on the reaction chamber 24, the lifting motor 138 is driven and the lifting bolt 140 is rotated by means of a pulley 144, so that the lifting nut 142 ascends and the lifting panel 136 ascends along the rail 134.

Thereafter, the coupling bracket 126 and the bracket mounting ring 130 integrally coupled to the lifting panel 136 and the exhaust nozzle 78 connected to them ascend together. Accordingly, the suction portion of the exhaust nozzle is inserted between the holders 10 and surrounds the lower portion of the outer circumference of the semiconductor substrate 100.

Here, the bellows cover 89 attached to the coupling bracket 126, is compressed to maintain the airtight between the exhaust pipe 79 and the reaction chamber 24.

Continuously, the driving device is connected to the susceptor 18 and the heater 80 is inserted into the inner space of the susceptor 18 through the loading device (not shown) to treat the process of the semiconductor substrats 100. After the process treatment is completed, it is progressed in reverse order of the above process (note FIG. 7c).

Therefore, the semiconductor manufacturing process using the semiconductor manufacturing device according to the present invention is performed.

That is, the semiconductor manufacturing method for processing the opposed semiconductor substrates 100 according to the present invention includes the steps of loading a pair of the opposed semiconductor substrates on the reaction chamber 24 for providing the airtight process space, connecting the driving shaft to a pair of driving roller 20′ among the support rollers 20 of the susceptors 18 in order to process the opposed semiconductor substrates 100, approaching the heating surface of the heater 80 to the back of the semiconductor substrates 100, inserting the exhaust nozzle 78 for surrounding the lower portion of the semiconductor substrate 100 into the space between the opposed holders 10, and processing the opposed semiconductor substrates 100.

Here, in the processing device loading step, the driving shaft connected to the driving roller 20′, the heater 80 moved toward the back of the semiconductor substrate, and the exhaust nozzle 78 inserted into the space between the opposed holders 10 maintain the moving and the airtight thereof by means of the bellows cover 69, 87, and 89 respectively.

In the meantime, the processing step further includes the back side evaporation disturbing step for disturbing the evaporation of the back of the semiconductor substrate 100 by supplying the purge gas to each back side of the opposed semiconductor substrates and the antifouling step for preventing the penetration of the minute dust in the direction of the inside of the opposed susceptors 18 by supplying the purge gas to the outer circumference of the each semiconductor substrate and forming the gas curtain portion 34 between each susceptor 18 and the supporting rollers 20 located at the circumference of each susceptor 18.

Also, the processing step further includes a heat treating step for heating the opposed semiconductor substrates 100 in the direction of the back of each semiconductor substrates through the heater 80 having the heating surface for receiving the whole area of the semiconductor substrates 100. Here, the heating region concentric to the semiconductor substrates includes a central portion 102 for heating the center of the semiconductor substrates 100, a peripheral portion 104 for heating the outside of the center of the semiconductor substrates 100 and surrounding the central portion 102, an outer circumference portion 106 for heating the outer circumference of the semiconductor substrates 100 and surrounding the peripheral portion 104, and a buffer portion 108 surrounding the outer circumference portion 106 and for heating it so as to alleviate the interference between the outer circumference portion 106 and the room temperature. Here, the peripheral portion 104, the outer circumference portion 106 and the buffer portion 108 divide into at least two vertical partitions corresponding to the upper and lower portions of the semiconductor substrates 100 respectively.

Here, the upper portion of the buffer portion 108 connected to the gateway of the supply nozzle 76 of the reaction gas allows the reaction gas to preheat and then, the preheated gas is injected. Also, the upper portion of the outer circumference portion 106 corresponding to the gateway of the supply nozzle 76 of the reaction gas and the space between the semiconductor substrates 100 allows the injected gas to heat and then, the heated gas is supplied to the semiconductor substrates 100.

As can be seen from the foregoing, in the semiconductor manufacturing device and the method thereof, there is an effect, in that the opposed semiconductor substrates keep standing and are rotated and the front and the outer circumference end of each substrate are supported by holders through the supporting panel, whereby preventing the transformation of the substrate through the elastic attaching means of the holder and sufficiently supporting the substrate under the environment of the high temperature.

Also, there is another effect in that the antifouling means is formed at the circumference of the susceptor 18, so that it can prevent the minute dust generated through the supporting roller from being penetrated into the process space of the semiconductor substrate, whereby decreasing the badness of the substrate.

Furthermore, there is further another effect in that the driving device is directly connected to the susceptor, whereby minutely controlling the revolution number of the susceptor.

Moreover, there is further another effect in that the driving device is sealed together with the reaction chamber by means of the bellows cover interposed between them and is provided with the cooling device, whereby maintaining the airtight of the reaction chamber and preventing the heat transformation of the driving shaft.

Also, there is further another effect in that the heating region of the heater divides into a plurality of radial portions, so that it can control the heating region in detail according to the external conditions, whereby forming the uniform temperature gradient of the semiconductor substrate.

In the meantime, there is further another effect in that the heater and the reaction chamber are combined with the bellows cover interposed between them and the heater is arranged closely to the rear of the semiconductor substrate during the loading, whereby allowing the moving of the heater and sufficiently maintaining the airtight of the reaction chamber.

Also, there is further another effect in that the heater is coupled to the heat mounting ring throuh the guide rail, whereby easily attaching and deattaching the heater.

Moreover, there is further another effect in that the exhaust nozzle is separated from the reaction chamber and loaded on the space between the substrates by means of the lifting device after the loading of the boat, so that the exhaust nozzle having a sufficient suction portion is loaded between the opposed substrates, whereby ensuring the reliance of the device.

While this invention has been described in connection with what are presently considered to be the most practical and preferred embodiments, it is to be understood that the invention is not limited to the disclosed embodiments and the drawings, but, on the contrary, it is intended to cover various modifications and variations within the spirit and scope of the appended claims.

What is claimed is:

1. A semiconductor manufacturing device comprising:
a reaction chamber for providing an airtight process space;
a boat for putting in the reaction chamber comprising a pair of susceptors for elastically attaching a pair of holders of a ring type thereto and mounting opposed semiconductor substrates therein so as to perform a heat treatment in the direction of a back of the opposed semiconductor substrates in the reaction chamber and a plurality of support rollers for rotating the susceptors;
a driving device for driving a pair of driving rollers among the support rollers and rotating the susceptors after putting the boat in the reaction chamber;
a pair of heaters arranged at the back of the opposed semiconductor substrates in order to perform the heat treatment of the semiconductor substrates in the reaction chamber;
a loading device for inserting the heaters into an inner space of the susceptors after putting the boat in the reaction chamber and approaching each heating surface of the heaters to the back of the opposed semiconductor substrates;
a supply nozzle for enveloping an upper portion of the opposed semiconductor substrates;
an exhaust nozzle for enveloping a lower portion of the opposed semiconductor substrates; and
a lifting device for standing by the exhaust nozzle at the lower portion of the opposed semiconductor substrates so as to evade the interference with the holder prior to the loading/withdrawal of the boat and inserting the exhaust nozzle between the holders in order to envelope the lower portion of the opposed semiconductor substrates next to the loading of the boat.

2. A semiconductor manufacturing device as claimed in claim 1 wherein, in each susceptor, a support panel is mounted at the back of the holder and elastically attached through an elastic attaching means so as to support the semiconductor substrate together with the holder by contacting with a peripheral of the back of the semiconductor substrate.

3. A semiconductor manufacturing device as claimed in claim 1 wherein, in each susceptor, an antifouling means is formed at the circumference of the susceptor 18 between the supporting roller and the mounted semiconductor substrate in order to prevent the penetration of an external particle in the direction of the mounted semiconductor substrate, the antifouling means having an antifouling ring protruded from a circumference of the susceptor in the direction of the semiconductor substrate in respect to a driving circumference portion and the supporting rollers.

4. A semiconductor manufacturing device as claimed in claim 1 wherein, in each susceptor, an antifouling means is formed at the circumference of the susceptor 18 between the supporting roller and the mounted semiconductor substrate in order to prevent the penetration of an external particle in the direction of the mounted semiconductor substrate, a purge gas supplying portion for supplying a purge gas to a space between the opposed susceptors is formed in the reaction chamber, and a gas curtain portion is formed in the antifouling means.

5. A semiconductor manufacturing device as claimed in claim 1 wherein another purge gas supplying portion is formed at the reaction chamber in order to supply a purge gas for disturbing an evaporation of the back of the semiconductor substrate from the opposed susceptors to the back of the semiconductor substrate.

6. A semiconductor manufacturing device as claimed in claim 1 wherein the driving device comprises a supporting frame formed at an outside of the reaction chamber, a transferring panel for sliding along a rail formed at the supporting frame, a transferring device for going and returning the transferring panel formed at the supporting frame, a driving motor having a driving shaft for rotating the driving roller formed at the transferring panel, and a connecting means connected to the driving shaft.

7. A semiconductor manufacturing device as claimed in claim 6 wherein the transferring device comprises a transferring motor formed at the supporting frame, a transferring bolt as a driving shaft connected to the transferring motor, a transferring nut coupled to the transferring bolt, and a supporting rod coupled to the transferring nut together with a buffer spring and coupled to the transferring panel.

8. A semiconductor manufacturing device as claimed in claim 6 wherein the driving shaft is spline-coupled to the connection means and a guide tapper surface for inducing the spline-couple is formed at a front end of driving shaft.

9. A semiconductor manufacturing device as claimed in claim 6 wherein, in order to maintain an airtight between the driving shaft and the reaction chamber, the driving shaft is penetrated through the reaction chamber, a reaction chamber mounting ring is formed at a through hole of the reaction chamber, a sealing means for sealing the outer circumference of the driving shaft is separated from the reaction chamber, and a bellows tube for maintaining the moving of the driving shaft and sealing the outer circumference of the driving shaft is formed between the sealing means and the reaction chamber mounting ring.

10. A semiconductor manufacturing device as claimed in claim 6 wherein the driving shaft is made of an insulating material so as to prevent a heat from transmitting to the driving motor and is spline-coupled to the rotating shaft of the driving motor through a coupler.

11. A semiconductor manufacturing device as claimed in claim 6 wherein the driving shaft comprises a cooling device having a cooling waterway and a cooling water connector of a ring type for supplying and discharging the cooling water to the cooling waterway of the rotated driving shaft formed at the gateway of the cooling waterway.

12. A semiconductor manufacturing device as claimed in claim 1 wherein, in order to heat the opposed semiconductor substrates in the direction of a back of each semiconductor substrate, the heater has a heating region for receiving the whole area of the semiconductor substrates having a separated power supplying line and concentric to the semiconductor substrates, the heating region comprising a central portion for heating the center of the semiconductor substrates, a peripheral portion for heating the outside of the center of the semiconductor substrates and surrounding the central portion, an outer circumference portion for heating the outer circumference of the semiconductor substrates and surrounding the peripheral portion, and a buffer portion surrounding the outer circumference portion and for heating it so as to alleviate the interference between the outer circumference portion and the room temperature.

13. A semiconductor manufacturing device as claimed in claim 12 wherein the peripheral portion, the outer circumference portion and the buffer portion divide into at two vertical partitions corresponding to the upper and lower portions of the semiconductor substrates respectively.

14. A semiconductor manufacturing device as claimed in claim 12 wherein the upper portion of the buffer portion connected to the gateway of the supply nozzle of the reaction gas serves to preheat the reaction gas prior to injecting it.

15. A semiconductor manufacturing device as claimed in claim 12 wherein the upper portion of the outer circumference portion corresponding to the gateway of the supply nozzle of the reaction gas and the space between the semiconductor substrates serves to heat the reaction gas supplied to the semiconductor substrates next to injecting it.

16. A semiconductor manufacturing device as claimed in claim 12 wherein the heating region of the heater further comprises a plurality of winding resistance heating lines having a supplying line and a grounding line adjacent to each other.

17. A semiconductor manufacturing device as claimed in claim 1 wherein the heater further comprises a loading device inserted into a back of the semiconductor substrates mounted to the susceptors after mounting the susceptors to the reaction chamber and the heater is hermetically mounted to the reaction chamber by means of a bellows cover.

18. A semiconductor manufacturing device as claimed in claim 17 wherein the bellows cover comprises a reaction chamber mounting ring surrounding the circumference of a through hole of the reaction chamber in order to load the heater, a heater mounting ring combined with the loading device inserted into the back of the semiconductor substrates, a bellows tube for sealing the space between the reaction chamber mounting ring and the heat mounting ring and allowing the moving thereof through the loading device, and a guide rail for attaching and deattaching the heater formed at the heater mounting ring, the heater being slid along the guide rail and coupled to the heat mounting ring.

19. A semiconductor manufacturing device as claimed in claim 1 wherein the exhaust nozzle comprises an exhaust pipe penetrated through the reaction chamber and formed at the outside thereof and a bellows cover for maintaining the moving of the exhaust pipe and performing the airtight thereof formed between the exhaust pipe and the reaction chamber.

20. A semiconductor manufacturing device as claimed in claim 19 wherein the bellows cover of the exhaust nozzle comprises a reaction chamber mounting ring surrounding the circumference of a through hole of the reaction chamber for arrangement of the exhaust pipe of the exhaust nozzle, a bracket mounting ring mounted to a coupling bracket of the lifting device for lifting the exhaust nozzle and having a packing for sealing the outer circumference of the exhaust pipe, and a bellows tube for sealing the space between the reaction chamber mounting ring and the bracket mounting ring and allowing the lifting of the exhaust pipe through the loading device.

21. A semiconductor manufacturing device as claimed in claim 1 wherein the lifting device comprises a supporting frame formed at the outside of the reaction chamber, a lifting panel for sliding along a rail formed at the supporting frame, the coupling bracket mounted to the lifting panel and coupled to the exhaust pipe of the exhaust nozzle, a lifting motor formed at the supporting frame, a lifting bolt as a driving shaft connected to the lifting motor, and a lifting nut coupled to and lifted up and down the lifting bolt and combined with the lifting panel.

22. A semiconductor manufacturing device as claimed in claim 1 wherein the standby chamber for standing by the exhaust nozzle is formed at the lower portion of the reaction chamber.

23. A semiconductor manufacturing device as claimed in claim 22 wherein a purge exhaust pipe for removing the purge gas is connected to the standby chamber.

24. A semiconductor manufacturing method comprising the steps of:
loading a pair of a pair of opposed semiconductor substrates on the reaction chamber for providing an airtight process space;
loading a processing device in the reaction chamber comprising the steps of connecting a driving shaft to a pair of driving roller among the support rollers of susceptors in order to process the opposed semiconductor substrates, approaching a heating surface of a heater to a back of the semiconductor substrates, and inserting an exhaust nozzle for surrounding a lower portion of the semiconductor substrate into a space between opposed holders; and
processing the opposed semiconductor substrates after the processing device loading step.

25. A semiconductor manufacturing method as claimed in claim 24 wherein, in the processing device loading step, the driving shaft connected to the driving roller, the heater moved toward the back of the semiconductor substrate, and the exhaust nozzle inserted into the space between the opposed holders maintain the moving and the airtight thereof respectively.

26. A semiconductor manufacturing method as claimed in claim 24 wherein, the processing step further comprises a back side evaporation disturbing step for disturbing the evaporation of the back of the semiconductor substrate by supplying the purge gas to each back side of the opposed semiconductor substrates.

27. A semiconductor manufacturing method as claimed in claim 24 wherein, the processing step further comprises an antifouling step for preventing a penetration of a minute dust in the direction of an inside of the opposed susceptors by supplying a purge gas to an outer circumference of the each semiconductor substrate and forming a gas curtain portion between each susceptor and the supporting rollers located at the circumference of each susceptor.

28. A semiconductor manufacturing method as claimed in claim 24 wherein the processing step further comprises a heat treating step for heating the opposed semiconductor substrates in the direction of the back of each semiconductor substrates through the heater having the heating surface for receiving a whole area of the semiconductor substrates, a heating region of the heater concentric to the semiconductor substrates comprising a central portion for heating the center of the semiconductor substrates, a peripheral portion for heating the outside of the center of the semiconductor substrates and surrounding the central portion, an outer circumference portion for heating the outer circumference of the semiconductor substrates and surrounding the peripheral portion, and a buffer portion surrounding the outer circumference portion and for heating it so as to alleviate the interference between the outer circumference portion and the room temperature and the peripheral portion, the outer circumference portion and the buffer portion being divided into at least two vertical partitions corresponding to the upper and lower portions of the semiconductor substrates respectively.

29. A semiconductor manufacturing method as claimed in claim 28 wherein the upper portion of the buffer portion connected to the gateway of the supply nozzle of the reaction gas allows the reaction gas to preheat and then, the preheated gas is injected.

30. A semiconductor manufacturing method as claimed in claim 28 wherein the upper portion of the outer circumference portion corresponding to the gateway of the supply nozzle of the reaction gas and the space between the semiconductor substrates allows the injected gas to heat and then, the heated gas is supplied to the semiconductor substrates.
